(19) United States
(12) Patent Application Publication
(10) Pub. No.: US 2026/0054666 A1
(43) Pub. Date: Feb. 26, 2026

(54) MODULAR ACCESSORY PANELS WITH INTEGRATED CONNECTIVITY AND POWER

(71) Applicant: Ford Global Technologies, LLC, Dearborn, MI (US)

(72) Inventors: Ming Hong Choi, Lasalle (CA); Matthew B. Rutman, Westland, MI (US)

(21) Appl. No.: 18/810,661

(22) Filed: Aug. 21, 2024

(51) Int. Cl. B60R 16/033; B60P 1/64; B60R 11/00; B60R 16/023

(52) U.S. Cl. CPC B60R 16/033; B60R 16/0238; B60P 1/6481; B60R 2011/005

(57) ABSTRACT

An apparatus comprises at least one base plate that is selectively attachable to a support surface. Each base plate includes a plurality of mounting apertures configurable to receive mounting feet from one or more accessories, a plurality of bus bars, and at least one power interface aperture. Each base plate includes also includes a plurality of contact openings that are open to the external surface, wherein each contact opening exposes an electrical contact surface of one of the plurality of bus bars.

### TECHNICAL FIELD

This disclosure relates generally to a modular base plate configuration powered by a main power supply to power accessories attached to the base plate, and more particularly to a modular base plate configuration: that can accept smaller accessories via exposed electrical contact surfaces; that can use an external power source to power the base plate when the main power supply is unavailable; and/or that can communicate baseplate/accessory information to a remote device.

### BACKGROUND

Vehicles transport various types of cargo including accessories, such as bins, containers, and tools, for example. The accessories can vary in size/shape and may require a power source. Support surfaces in a vehicle cargo area or other type of work area may be configured to securely support the accessories.

### SUMMARY

In some aspects, the techniques described herein relate to an apparatus, including: at least one base plate that is selectively attachable to a support surface, wherein each base plate has an external surface and includes: a plurality of mounting apertures configurable to receive mounting feet from one or more accessories; a plurality of bus bars; at least one power interface aperture; and a plurality of contact openings that are open to the external surface, wherein each contact opening exposes an electrical contact surface of one of the plurality of bus bars.

In a further non-limiting embodiment of any apparatus, the plurality of bus bars comprises a plurality of positive bus bars and a plurality of negative bus bars, and wherein the plurality of contact openings are arranged in pairs such that in each pair: one contact opening exposes the electrical contact surface of one positive bus bar, and one contact opening exposes the electrical contact surface of one negative bus bar.

In a further non-limiting embodiment of any apparatus, the pairs comprise at least a first pair of contact openings positioned and a second pair of contact openings, and including at least one accessory with a plurality of electrical contacts that are selectively connectable to one of the first pair of contact openings and the second pair of contact openings.

In a further non-limiting embodiment of any apparatus, the plurality of positive bus bars and the plurality of negative bus bars are arranged in a grid pattern with each positive bus bar overlapping at least one negative bus bar at an intersection in a non-contact relationship.

In a further non-limiting embodiment of any apparatus, the plurality of electrical contacts are arranged in pairs such that each pair of electrical contacts is selectively connectable to a selected pair of any of the pairs of contact openings.

In a further non-limiting embodiment of any apparatus, the at least one accessory is mountable on the at least one base plate in one of a plurality of different mounting configurations, and wherein the pairs of electrical contacts comprise at least a first pair of electrical contacts and a second pair of electrical contacts, and wherein in each mounting configuration one of the first pair of electrical contacts and second pair of electrical contacts is in a power connected position with one of the first pair of contact openings or second pair of contact openings, and the other of the first pair of electrical contacts and second pair of electrical contacts is in non-power connected position.

In a further non-limiting embodiment of any apparatus, the support surface is associated with at least one of a vehicle and a work area removed from the vehicle.

In a further non-limiting embodiment of any apparatus, a power connection interface is associated with the at least one base plate, wherein the power connection interface provides power from a main power source to the at least one base plate via the plurality of bus bars.

In a further non-limiting embodiment of any apparatus, at least one external power source is connectable to the at least one base plate to supply power to the plurality of bus bars when the main power source is unavailable.

In a further non-limiting embodiment of any apparatus, the at least one external power source comprises at least one of: a portable battery with an inductive charger associated with the at least one power interface aperture; a portable battery that is docked on the at least one base plate via the plurality of contact openings.

In a further non-limiting embodiment of any apparatus, a communication device is associated with the at least one base plate, wherein the communication device communicates information from one or more accessories connected to the at least one base plate to a remote device.

In a further non-limiting embodiment of any apparatus, the communication device is at least partially embedded within the at least one base plate and comprises a communication protocol including one or more of Wi-Fi, Bluetooth, USB, NFC.

In some aspects, the techniques described herein relate to a method of attaching at least one accessory to the apparatus of claim 1 and further includes: selectively connecting electrical contacts on the at least one accessory with contact openings from the plurality of contact openings.

In some aspects, the techniques described herein relate to a method of powering the apparatus of claim 8 and further includes: connecting at least one external power source to the at least one base plate to supply power to the plurality of bus bars when the main power source is unavailable.

In a further non-limiting embodiment of any apparatus, the at least one external power source comprises a portable battery with an inductive charger, and the method includes associating a transmitter of the portable battery with the inductive charger with a receiver associated with the at least one base plate at the at least one power interface aperture; and/or the at least one external power source comprises a portable battery, and including docking the portable battery on the at least one base plate via the plurality of contact openings.

In some aspects, the techniques described herein relate to a method of communicating with the apparatus of claim 1 and further includes: associating a communication device with the at least one base plate; communicating information from one or more accessories connected to the at least one base plate to the communication device; and communicating information related to the at least one base plate and/or associated accessories to a remote device.

In some aspects, the techniques described herein relate to an apparatus, including: at least one base plate that is selectively attachable to a support surface, wherein each base plate has an external surface and includes: a plurality of mounting apertures configurable to receive mounting feet from one or more accessories; a plurality of bus bars; and at least one power interface aperture; a power connection interface associated with the at least one base plate, wherein the power connection interface provides power from a main power source to the at least one base plate via the plurality of bus bars; and at least one external power source that is connectable to the at least one base plate to supply power to the plurality of bus bars when the main power source is unavailable.

In a further non-limiting embodiment of any apparatus, the at least one external power source comprises at least one of: a portable battery with an inductive charger associated with the at least one power interface aperture; a portable battery mounted on the at least one base plate, wherein the at least one base plate includes a plurality of contact openings that are open to the external surface, wherein each contact opening exposes an electrical contact surface of one of the plurality of bus bars, and the portable battery is docked on the at least one base plate via the plurality of contact openings.

In some aspects, the techniques described herein relate to an apparatus, including: at least one base plate that is selectively attachable to a support surface, wherein each base plate has an external surface and includes: a plurality of mounting apertures configurable to receive mounting feet from one or more accessories; a plurality of bus bars; and at least one power interface aperture; a power connection interface associated with the at least one base plate, wherein the power connection interface provides power from a main power source to the at least one base plate via the plurality of bus bars; and a communication device associated with the at least one base plate, wherein the communication device communicates information from one or more accessories connected to the at least one base plate to a remote device.

In a further non-limiting embodiment of any apparatus, the apparatus includes: at least one external power source that is connectable to the at least one base plate to supply power to the plurality of bus bars when the main power source is unavailable; and/or at least one accessory with a plurality of electrical contacts, wherein the at least one base plate includes a plurality of contact openings that are open to the external surface, wherein each contact opening exposes an electrical contact surface of one of the plurality of bus bars, and wherein the plurality of electrical contacts are selectively connectable to the plurality of contact openings.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE FIGURES

The various features and advantages of the disclosed examples will become apparent to those skilled in the art from the detailed description. The figures that accompany the detailed description can be briefly described as follows:

FIG. 1A illustrates a perspective view of a vehicle having a cargo area equipped with base plates that can be used to secure an accessory according to an exemplary aspect of the present disclosure.

FIG. 1B is similar to FIG. 1A but shows a different type of vehicle.

FIG. 2 is a schematic illustration of an accessory that is mountable to a base plate.

FIG. 3 is a perspective view of a modular base plate as mounted to wall studs.

FIG. 4 a front view of the modular base plate of FIG. 3.

FIG. 5 is a front view of a modular plate structure comprised of a plurality of base plates that are powered from a power source.

FIG. 6 is a front view of a plate structure with a plurality of exposed electrical contact surfaces.

FIG. 7 is a schematic section view of a pair of posed electrical contact surfaces from the plate structure of FIG. 6 engaging electrical contacts of an accessory.

FIG. 8 is a front view of a plate structure with external power sources in a back feed arrangement.

FIG. 9 is a schematic representation of a plate structure with integrated connectively.

### DETAILED DESCRIPTION

The subject disclosure provides a modular base plate mounting structure having a plurality of mounting apertures to which various types of accessory structures can be selectively secured via an attachment interface. The attachment interface includes mounting feet or cleats that are inserted into the mounting apertures. The base plates can be mounted inside a vehicle, or outside of a vehicle to a floor structure or a wall structure in various configurations. The modular base plate is connectable to a main power supply to supply power to accessories mounted to the base plates. The subject disclosure provides for a configuration that can accept smaller accessories via exposed electrical contact surfaces, that can use an external power source to power the base plate when the main power supply is unavailable, and/or that can communicate baseplate/accessory information to a remote device.

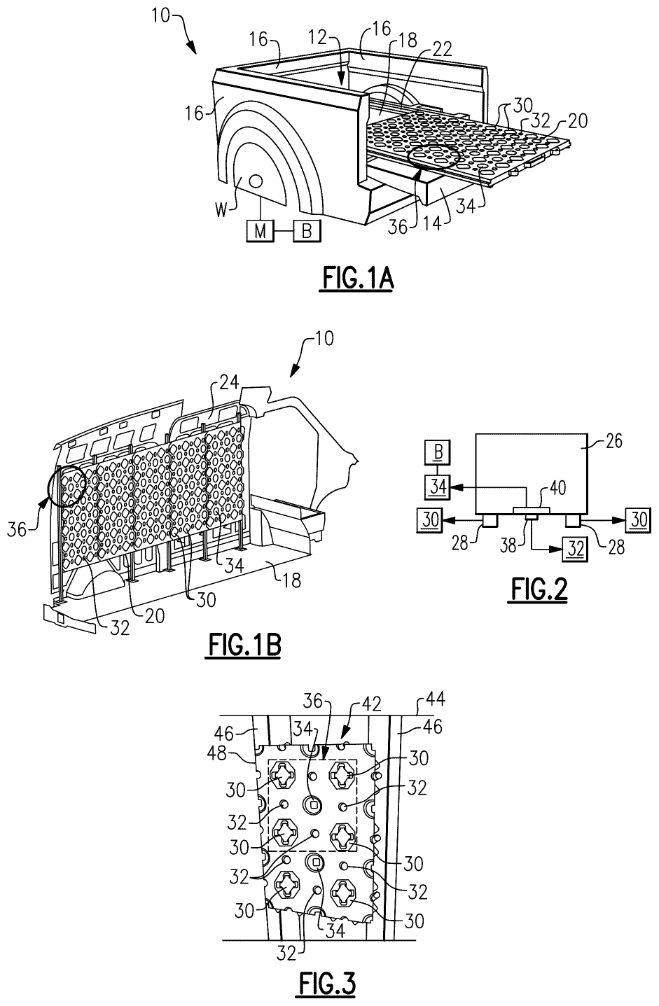

FIGS. 1A and 1B show a vehicle 10 that includes a cargo area 12 that is aft of a passenger compartment (not shown). A tailgate 14 is moveable between open and closed positions to enclose one end of the cargo area 12. The cargo area 12 is further defined by side walls 16 and a floor 18 that supports one or more base plates 20. In this example, the base plates 20 are slidable out of the cargo area 12 on a rail or track system 22 such that the base plates 20 can be removed from the cargo area 12 when the tailgate 14 is in the open position.

In this example, the vehicle 10 is a pickup truck. However, the vehicle 10 could be another type of vehicle in another example, such as a car, van, sport utility vehicle, etc. FIG. 1B shows an example of a vehicle 10 that comprises a van that incorporates one or more base plates 20 onto an upright wall 24.

In one example, the vehicle 10 includes an electrified powertrain capable of applying a torque from an electric machine M (e.g., an electric motor) to drive a least one set of wheels W. The vehicle 10 can include a traction battery pack B, which powers the electric machine M and, potentially, other electrical loads of the vehicle 10. The example vehicle 10 may be an electrified vehicle and, in particular, a battery electric vehicle (BEV). In another example, the vehicle 10 could be another type of electrified vehicle, such as a plug-in hybrid electric vehicle (PHEV), or a conventional vehicle.

The base plates 20 are configured to provide an accessory attachment system where various different types of accessories 26 with mounting feet/cleats 28 that can be selectively attached and detached from the base plates 20. For example, as shown in FIGS. 1A and 1B, the base plates 20 are formed with a plurality of mounting apertures 30 that are configured to receive the mounting feet/cleats 28 of attachment accessories 26. In one example, the base plates 20 also include locking apertures 32 to lock the accessory 26 to the base plate 20 as needed, and power interface apertures 34 to provide power to the accessories 26 as needed.

As shown in FIG. 2, an example accessory 26 includes one or more mounting feet or cleats 28. The accessory 26 can engage the base plate 20 by inserting each mounting cleat 28 into a single mounting aperture 30 to provide a mechanical connection interface. The mounting apertures 30 are spaced upwardly from the floor 18 or side walls 16, 24 by an open gap such that the mounting cleats 28 can be easily inserted into the base plate 20.

As discussed above, the base plate 20 includes a plurality of apertures. In one example, the plurality of apertures are divided into sub-groups 36 of apertures that include at least one type of each different aperture 30, 32, 34. In one example, the power interface apertures 34 and locking apertures 32 of the base plate 20 are spaced apart and separate from each other and from the mounting apertures 30. In one example, the apertures 30, 32, 34 can have shapes and/or sizes that are different from each other. The sub-groups 36 of apertures 30, 32, 34 are provided at multiple locations on the base plate 20, and are formed in a desired pattern on the base plate 20 to allow for the accessories 26 to be mounted in various different locations as needed. In one example, the mounting apertures 30 are formed to have a diamond shape and are larger in size than the power apertures 34 and locking apertures 32.

In one example, the sub-group 36 comprises mounting apertures 30 that are formed in a four corner pattern with a center power aperture 34 between the four corners, and with locking apertures 32 between adjacent mounting apertures 30. This pattern provides for easy and quick connect/disconnect.

In one example, the accessory 26 includes at least one lock 38 that is separate from the mounting feet/cleats 28. Thus, the various accessories 26 can be secured to the vehicle 10 by engaging one or more of the mounting apertures 30 in the base plates 20 via the mounting cleats 28 and then actuating the lock 38 into one of the locking apertures 32. The accessories 26 can comprise, for example, a lockable storage box that holds clothing, tools, a refrigerator, etc. The accessory 26 could also be a lidded lockable container that includes a compartment for storing power tools or other items that require data connection or power connection via the power interface apertures 34. In this configuration, the accessory 26 includes a power interface 40, as schematically shown in FIG. 2 that interacts with the power interface apertures 34. This would allow devices within the accessory 26 to be powered from a vehicle power supply such as the battery pack B, 12V vehicle power, or other power sources via a variety of connections/outlets, for example. Examples of such a power interface connection between an accessory and a base plate can be found in application Ser. No. 17/716,053 and application Ser. No. 17/716,048, which were both filed on Apr. 8, 2022, and which are assigned to the assignee of the subject application, and which are herein incorporated by reference in their entirety.

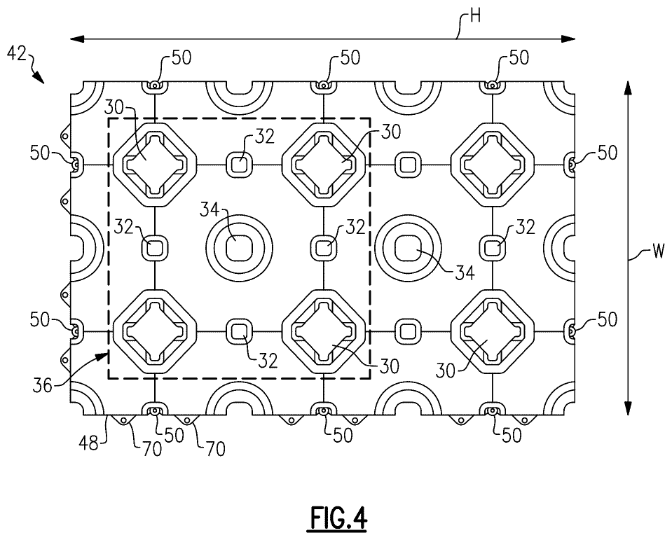

As discussed above, the base plates 20 with the apertures 30, 32, 34 can be mounted to the walls 16, 24 or the floor 18 in the cargo area 12 in a first base support application. The base plates 20 also have a base plate mounting configuration, i.e., a second base support application, that can be used on walls 44 (FIG. 3) in a stationary, non-vehicle application that is remote from the vehicle, e.g., a utility trailer, a garage or a shop, to allow accessories to be moved back and forth between the vehicle 10 and a permanent work area.

In one example, the base plates are made from a material that comprises a composite plastic material that is strong enough to hold large loads but also slightly flexible to resist cracking when dropped, or breaking, when attachment fasteners are tightened. Examples of composite plastic materials include, for example, fiber-reinforced composites, carbon fiber composites, glass fiber composites, etc.

In one example shown in FIGS. 3-4, a modular base plate 42 is shown that can be mounted directly to wall studs 46, for example. In one example, each modular base plate 42 is sized as a sixteen inch width W by twenty-four inch height H (16″×24″) plate, which is able to be mounted on sixteen inch (16″) and twenty-four inch (24″) stud spacing as typically used in construction. In this example, each modular base plate 42 includes mounting apertures 30 with a diamond shape, locking apertures 32, and power interface apertures 34 on 8″ spacing; however, other spacing configurations could also be used. The plurality of apertures are comprised of the sub-groups 36 that each comprise a predetermined pattern that includes at least one mounting aperture 30, at least one locking aperture 32, and at least one power interface aperture 34, and wherein the predetermined pattern is the same for the first base support application and the second base support application. This allows accessories 26 to be selectively detached from one type of base plate 20 or 42 and then selectively attached to the other of the type of base plate 20 or 42.

In one example, for each sub-group 36, the at least one mounting aperture 30 comprises a plurality of mounting apertures 30, the at least one locking aperture 32 comprises a plurality of locking apertures 32, and the at least one power interface aperture 34 comprises a single power interface aperture 34. This type of configuration allows for accessories 26 to be easily installed on the plates in multiple different orientations and rotational positions. In one example, each sub-group 36 includes four mounting apertures 30, four locking apertures 32, and a single power interface aperture 34.

FIG. 4 shows one example where each modular base plate 42 has an outer peripheral edge 48 that includes a plurality of mount features 50, wherein a first mount feature 50 on a modular base plate 42 overlaps a second mount feature 50 from an adjacent modular base plate 42 to secure two modular base plates 42 together at an attachment interface. An example of such an attachment interface between adjacent base plates can be found in application Ser. No. 18/676,737, which was filed on May 29, 2024, and which is assigned to the assignee of the subject application, and which is herein incorporated by reference in its entirety.

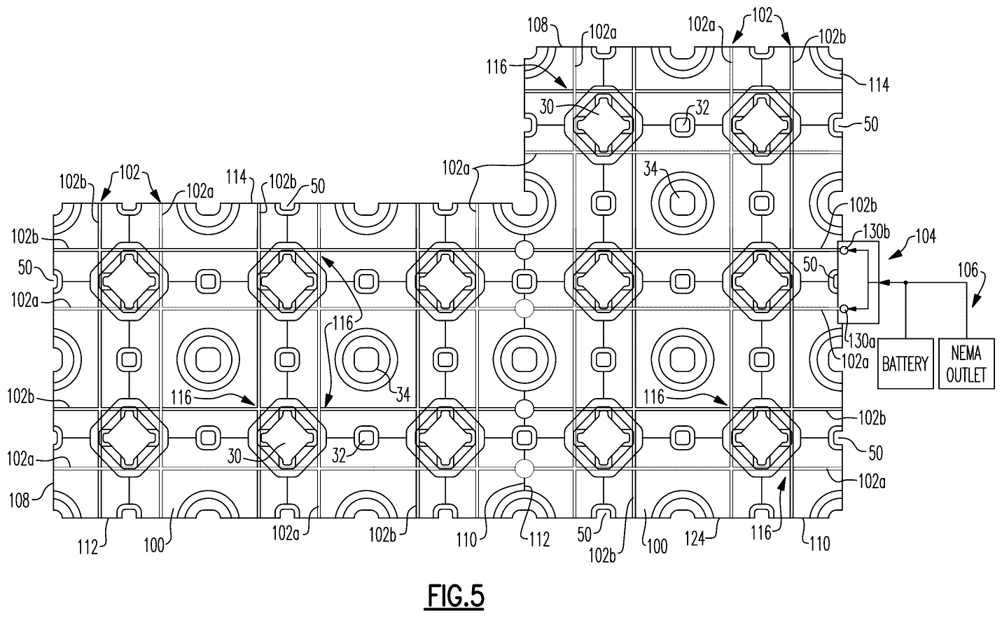

FIG. 5 shows an example of a powered base plate configuration. In one example, a plurality of modular base plates 100 are selectively attachable to a support surface, such as wall studs 46 for example, in a selected one of a plurality of different arrangements. Each modular base plate 100 includes a plurality of mounting apertures 30 configurable to receive mounting feet/cleats 28 from one or more accessories 26, a plurality of bus bars 102, and at least one power interface aperture 34. The modular base plate 100 may also include one or more locking apertures 32. In one example, a power connection interface 104 is associated with one of the modular base plates 100, wherein the power connection interface 104 provides power from a power source 106 to all modular base plates 100 in each base plate arrangement.

In one example, the plurality of bus bars 102 comprises a plurality of positive bus bars 102a and a plurality of negative bus bars 102b. In one example, the positive bus bars 102a and the negative bus bars 102b each extend from one edge of each modular base plate 100 to an opposite edge of each modular base plate 100. Each modular base plate 100 extends in a longitudinal direction from a first edge 108 to a second edge 110, and each modular base plate 100 extends in a lateral direction from a third edge 112 to a fourth edge 114. Some of the positive bus bars 102a and the negative bus bars 102b extend in the longitudinal direction from the first edge 108 to the second edge 110, and some of the positive bus bars 102a and the negative bus bars 102b extend in the lateral direction from the third edge 112 to the fourth edge 114. In this example, the bus bar arrangement comprises a grid pattern with positive bus bars 102 overlapping negative bus bars 102b at a plurality of intersections 116. The positive bus bars 102a and the negative bus bars 102b cannot touch each other at the intersections 116 such that there will be no possibility of short circuiting.

In implementations, the bus bars 102a, 102b are at least partially embedded within a body of the of the base plates 100 themselves. As discussed above, the base plates 100 are made from a composite plastic material, for example. In one example, the bus bars 102a, 102b are overmolded within the composite plastic material to form the base plates 100. Any type of molding process can be used, such as insert molding, two-shot molding, etc. Optionally, the bus bars 102a, 102b can be adhered to a rear surface of the base plates 100.

In implementations, the power source 106 comprises a main power supply for the base plates 100. An example of such a powered modular base plate configuration can be found in application Ser. No. 18/677,064, which was filed on May 29, 2024, and which is assigned to the assignee of the subject application, and which is herein incorporated by reference in its entirety.

The subject disclosure provides for a configuration with a base plate 200 (FIG. 6) that can continue to be powered when the main power supply 106 is off such that accessories can remain powered. This is useful for situations where the main power supply 106 is inactive, has been disconnected from the base plate 100, or is subject to a blackout, for example. In implementations for this configuration, the base plates 200 include a plurality of contact openings 202 that are exposed at an outward facing surface 204 of the base plate 200 to provide access to electrical contact surfaces of the bus bars 102a, 102b.

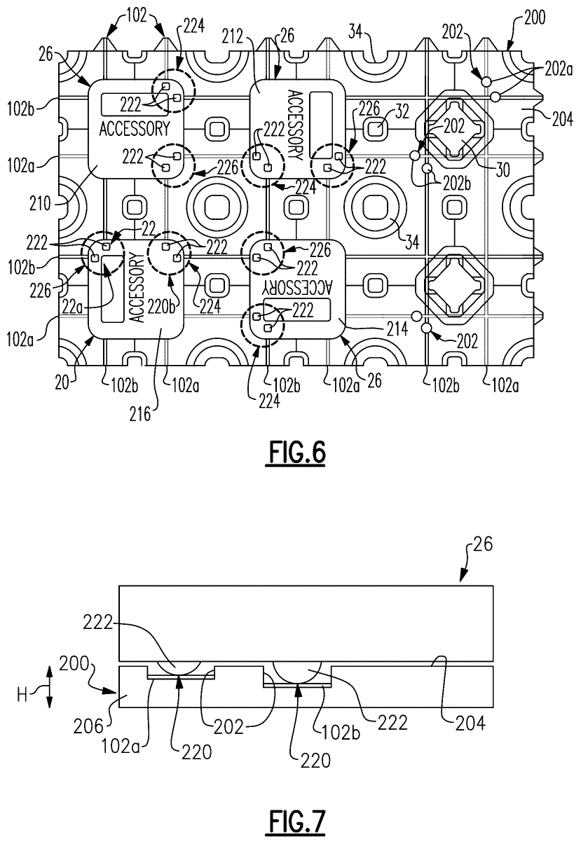

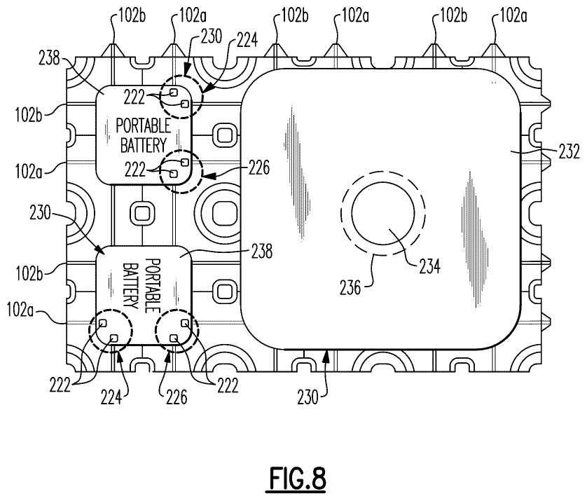

FIG. 7 shows a section of a molded plastic body 206 of the base plate 200 with the bus bars 102a, 102b exposed to the outward facing surface 204. As discussed above, the positive bus bars 102a and the negative bus bars 102b cannot touch each other at the intersections 116. In this example, the positive bus bars 102a and negative bus bars 102b are off-set from each other at each intersection 116 in at least one direction. The offset can be in one direction or multiple directions. FIG. 7 shows an example where the positive bus bars 102 and negative bus bars 102b are at least partially offset from each other in a height direction H, with the contact opening 202 for the negative bus bar 102 being deeper, e.g., having a greater height, than the contact openings 202 for the positive bus bar 102a. Thus, each bar of different polarity is on a different height and insulated from each other by way of material from the molded plastic body 206.

In certain implementations, smaller accessories that do not occupy a power interface aperture 34 location on a base plate will be unable to receive power from the plate. These accessories also may or may not include a mounting foot for insertion into the mounting apertures 30. The contact openings 202 that are exposed at an outward facing surface 204 of the base plate 200 provides power access to the bus bars 102a, 102b for such smaller accessories 26. Such accessories may include, for example, a camera, phone, smart device, battery charger, etc. The embedded electrical contacts in the base plates facilitate powering of these smaller accessories without the need for a wired connection to the accessory, and allows for data transfer between connected devices and plates. Additionally, the smaller accessories can touch contacts for power, rather than extend to the inductive charger area which increases required package space.

In one example, the contact openings 202 are located in strategic areas that allow for accessories 26 to contact at least one set of electrical contact surfaces, e.g., contact with one positive bus bar 102a and one negative bus bar 102b, for power transfer regardless of orientation of the accessory 26. In other words, the accessories 26 can be attached to the base plate 200 in one of any number of mounting orientations. FIG. 6 shows an example were the accessory 26 mounted in a first position 210, a second position 212 rotated ninety degrees relative to the first position 210, a third position 214 rotated ninety degrees relative to the second position 212, and a fourth position 216 rotated ninety degrees relative to the third position 214,

In implementations, to provide for this flexible mounting configuration, each mounting aperture 30 includes at least four contact openings 202. In one example, the four contact openings 202 comprise a first pair 202a at one corner location of the mounting aperture 30 and a second pair 202b at an opposite corner location of the mounting aperture 30. Each pair 202a, 202b must have access to one positive bus bar 102a electrical contact surface and one negative bus bar 102b electrical contact surface.

In implementations, the accessories 26 include electrical contacts 220 (FIG. 7) that are associated with the contact openings 202. In implementations, each accessory 26 includes at least four electrical contacts 220. In one example, the four electrical contacts 220 comprise a first pair 220a at one corner location of the accessory and a second pair 220b at an adjacent corner location of the accessory 26 (see configuration 216 in FIG. 6). Each pair 220a, 220b must have access to one positive bus bar 102a contact surface and one negative bus bar 102b contact surface.

In implementations, the electrical contacts 220 may comprise pogo pins 222 as shown in FIG. 7. A pogo pin is a type of spring-loaded electrical contact mechanism to establish a temporary electrical connection. In implementations, it may comprise a plunger, usually made of brass or steel for example, that is housed within a cylindrical body. The plunger is spring-loaded, allowing it to retract and extend when pressure is applied or released. Other types of spring-loaded or flexible electrical contacts may also be used.

As shown in FIG. 6, when the accessory 26 is mounted to the base plate 200 only one of the pairs of contacts 220a, 220b is in the correct position to electrically connect to one of the pairs 202a, 202b of contact openings. In other words, only one of the pairs of contacts 220a, 220b can be aligned to contact one positive bus bar 102a and one negative bus bar 102b, the other pair of contacts 220a, 220b are not aligned with contact openings because they are overlapping intersections of either two positive bus bars 102a or two negative bus bars 102b, and there are no contact openings at these types of intersections. Areas indicated at 224 in FIG. 6 identify correct electrical connections, e.g. powered connections, where there is pogo pin contact with one positive bus bar 102a and one negative bus bar 102b. Areas indicated at 226 in FIG. 6 identify pogo pins in non-powered connection where the pins are located at intersections of either two positive bus bars 102a or two negative bus bars 102b where there are no contact openings 202.

In certain implementations, the base plates may lose power if the primary power source 106 from a vehicle battery or wall outlet is interrupted. The subject disclosure also provides for a back feed power option where an external power source can be used to power the base plates. This provides for the capability to back feed power from portable batteries, for example, to the base plate system as a backup power source when the primary source is unavailable.

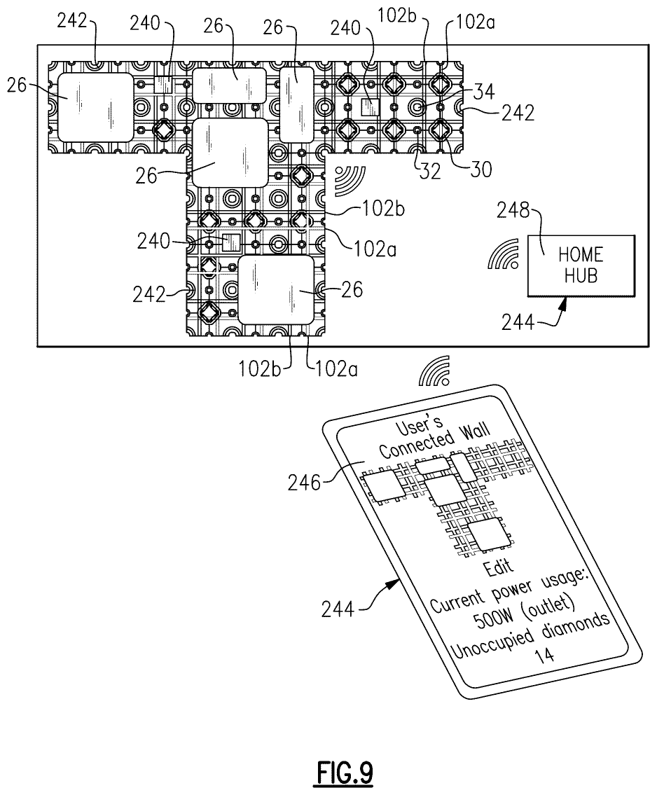

In implementations, one or more external power sources 230 (FIG. 8) can be used to power the base plate 200 when the primary power source 106 is unavailable. For example, an external power source 230, such as a portable battery 232 with an inductive charger, can transmit power in reverse, e.g., transmit power from the battery 232 to the plate 200. In this example, the battery 224 has a transmitter 234 and the plate 236 includes a receiver 236 to power the bus bars 102.

As such, the plate system can draw power from a portable battery 232 that is docked to a base plate when power is unavailable from the primary power source 106. For example, in a situation where base plates on a trailer lose power when a vehicle is powered off, the base plate can communicate this to the portable battery 232 and the battery 232 can then feed power to the plate system and other connected accessories. When the primary power source 106 is available, this is communicated to the portable battery 232 and the back feeding can be terminated.

In other implementations, the external power source 230 may comprise smaller portable batteries 238 that are docked to the base plate with pogo pins 220 such as that shown in FIG. 6.

Additionally, a plurality of portable batteries 232 and/or 238 can be docked on the plate to boost total available power output and capacity. Thus, power can be delivered to the base plate 200 via electrical contacts from the docked battery or inductively through an existing inductive charger on a base plate.

The subject disclosure also provides for integrated connectivity options such that the base plates, accessories, and remote devices are able to communicate with each other and to users. The base plates can communicate with each other to determine which docked accessories should be load shed if using a limited backup power source. The base plates can also communicate with other connected devices to broadcast a status or message.

FIG. 9 shows one example implementation of integrated connectivity where a device 240 is at least partially embedded in a plate 242 that provides integrated connectivity and communication protocols, e.g., Wi-Fi, Bluetooth®, Universal Serial Bus (USB), Near Field Communication (NFC), into the base plate 242 via physical or wireless connection interfaces to connected accessories 26. As long as the device 240 has access to power, either through the main power supply 106 or via the external power supply 230, the base plates can communicate with accessories 26 and/or external/remote devices 244.

In implementations, the accessories 26 communicate information/data to the base plate 242, which then communicates to the external device 244.

In implementations, the external device may comprise a smart device 246, e.g. phone, tablet, etc., a remote server or home hub 248, or any other similar remote device.

In one example, the information that is communicated to remote devices 244 can include one or more of the following: current power usage for each accessory attached to the unit, current power usage for all accessories attached to the unit, number of occupied diamond power connection interfaces, number of unoccupied diamond power connection interfaces (see FIG. 9).

In one example, the base plates may inform a connected remote device on an associated status of the plate itself such as power use, areas occupied by accessories, temperature, weight, etc.

In implementations, the plate 242 may include a back feed configuration as shown in FIG. 9 and/or an accessory connection interface as shown in FIGS. 6-7.

The preceding description is exemplary rather than limiting in nature. Variations and modifications to the disclosed examples may become apparent to those skilled in the art that do not necessarily depart from the essence of this disclosure. Thus, the scope of protection given to this disclosure can only be determined by studying the following claims.

What is claimed is:

1. An apparatus, comprising:
at least one base plate that is selectively attachable to a support surface, wherein each base plate has an external surface and includes:
a plurality of mounting apertures configurable to receive mounting feet from one or more accessories;
a plurality of bus bars;
at least one power interface aperture; and
a plurality of contact openings that are open to the external surface, wherein each contact opening exposes an electrical contact surface of one of the plurality of bus bars.

2. The apparatus of claim 1, wherein the plurality of bus bars comprises a plurality of positive bus bars and a plurality of negative bus bars, and wherein the plurality of contact openings are arranged in pairs such that in each pair:
one contact opening exposes the electrical contact surface of one positive bus bar, and
one contact opening exposes the electrical contact surface of one negative bus bar.

3. The apparatus of claim 2, wherein the pairs comprise at least a first pair of contact openings positioned and a second pair of contact openings, and including at least one accessory with a plurality of electrical contacts that are selectively connectable to one of the first pair of contact openings and the second pair of contact openings.

4. The apparatus of claim 3, wherein the plurality of positive bus bars and the plurality of negative bus bars are arranged in a grid pattern with each positive bus bar overlapping at least one negative bus bar at an intersection in a non-contact relationship.

5. The apparatus of claim 3, wherein the plurality of electrical contacts are arranged in pairs such that each pair of electrical contacts is selectively connectable to a selected pair of any of the pairs of contact openings.

6. The apparatus of claim 5, wherein the at least one accessory is mountable on the at least one base plate in one of a plurality of different mounting configurations, and wherein the pairs of electrical contacts comprise at least a first pair of electrical contacts and a second pair of electrical contacts, and wherein in each mounting configuration one of the first pair of electrical contacts and second pair of electrical contacts is in a power connected position with one of the first pair of contact openings or second pair of contact openings, and the other of the first pair of electrical contacts and second pair of electrical contacts is in non-power connected position.

7. The apparatus of claim 1, wherein the support surface is associated with at least one of a vehicle and a work area removed from the vehicle.

8. The apparatus of claim 1, including a power connection interface associated with the at least one base plate, wherein the power connection interface provides power from a main power source to the at least one base plate via the plurality of bus bars.

9. The apparatus of claim 8, including at least one external power source that is connectable to the at least one base plate to supply power to the plurality of bus bars when the main power source is unavailable.

10. The apparatus of claim 9, wherein the at least one external power source comprises at least one of:
a portable battery with an inductive charger associated with the at least one power interface aperture;
a portable battery that is docked on the at least one base plate via the plurality of contact openings.

11. The apparatus of claim 1, including a communication device associated with the at least one base plate, wherein the communication device communicates information from one or more accessories connected to the at least one base plate to a remote device.

12. The apparatus of claim 11, wherein the communication device is at least partially embedded within the at least one base plate and comprises a communication protocol including one or more of Wi-Fi, Bluetooth, USB, NFC.

13. A method of attaching at least one accessory to the apparatus of claim 1 including:
selectively connecting electrical contacts on the at least one accessory with contact openings from the plurality of contact openings.

14. A method of powering the apparatus of claim 8 including:
connecting at least one external power source to the at least one base plate to supply power to the plurality of bus bars when the main power source is unavailable.

15. The method of claim 14, wherein:
the at least one external power source comprises a portable battery with an inductive charger, and including associating a transmitter of the portable battery with the inductive charger with a receiver associated with the at least one base plate at the at least one power interface aperture; and/or
the at least one external power source comprises a portable battery, and including docking the portable battery on the at least one base plate via the plurality of contact openings.

16. A method of communicating with the apparatus of claim 1 including:
associating a communication device with the at least one base plate;
communicating information from one or more accessories connected to the at least one base plate to the communication device; and
communicating information related to the at least one base plate and/or associated accessories to a remote device.

17. An apparatus, comprising:
at least one base plate that is selectively attachable to a support surface, wherein each base plate has an external surface and includes:
a plurality of mounting apertures configurable to receive mounting feet from one or more accessories;
a plurality of bus bars; and
at least one power interface aperture;
a power connection interface associated with the at least one base plate, wherein the power connection interface provides power from a main power source to the at least one base plate via the plurality of bus bars; and
at least one external power source that is connectable to the at least one base plate to supply power to the plurality of bus bars when the main power source is unavailable.

18. The apparatus of claim 17, wherein the at least one external power source comprises at least one of:
a portable battery with an inductive charger associated with the at least one power interface aperture;
a portable battery mounted on the at least one base plate, wherein the at least one base plate includes a plurality of contact openings that are open to the external surface, wherein each contact opening exposes an electrical contact surface of one of the plurality of bus bars, and the portable battery is docked on the at least one base plate via the plurality of contact openings.

19. An apparatus, comprising:
at least one base plate that is selectively attachable to a support surface, wherein each base plate has an external surface and includes:
a plurality of mounting apertures configurable to receive mounting feet from one or more accessories;
a plurality of bus bars; and
at least one power interface aperture;
a power connection interface associated with the at least one base plate, wherein the power connection interface provides power from a main power source to the at least one base plate via the plurality of bus bars; and
a communication device associated with the at least one base plate, wherein the communication device communicates information from one or more accessories connected to the at least one base plate to a remote device.

20. The apparatus of claim 17, including:
at least one external power source that is connectable to the at least one base plate to supply power to the plurality of bus bars when the main power source is unavailable; and/or
at least one accessory with a plurality of electrical contacts, wherein the at least one base plate includes a plurality of contact openings that are open to the external surface, wherein each contact opening exposes an electrical contact surface of one of the plurality of bus bars, and wherein the plurality of electrical contacts are selectively connectable to the plurality of contact openings.
